(19) United States
(12) Patent Application Publication
(10) Pub. No.: US 2004/0244692 A1
(43) Pub. Date: Dec. 9, 2004

(54) Method to accurately and repeatably setup an ion beam for an ion implantation system in reduced setup time to increase productivity

(75) Inventors: Jiong Chen, San Jose, CA (US); Simeon K. S. Ma, Danvers, MA (US)

Correspondence Address: Bo-In Lin, 13445 Mandoli Drive, Los Altos Hills, CA, 94022, US

(73) Assignee: Advanced Ion Beam Technology, Inc.

(21) Appl. No.: 10/454,428

(22) Filed: Jun. 4, 2003

(51) Int. Cl. C23C 16/00

(52) U.S. Cl. 118/723 CB

(57) ABSTRACT

An ion implantation method is disclosed that includes a step of carrying out a built-in early check to ensure accurate and correct operation parameters are employed when the setup operation is started. By applying built-in check processes, the repeatability of ion beam setup processes can be enhanced. The ion beam setup method includes a formula-based searching algorithm to accurately and rapidly determines the atomic mass unit (AMU) using a feedback data other than the beam current. The same formula is used to check for subsystems consistency and reliability to ensure accuracy of the ion beam being set up. The searching algorithm further implements a peaking algorithm to avoid the common pitfalls of misinterpretation of data and achieve an accurate, reliable, and fast tuning with the help of “Trusty Recipes” as initial conditions and “Limits Parameters” as constraints. In order to enhance and facilitate the human-system interactions, graphic user interface (GUI) is used to minimize human errors and to monitor and to rapidly react to abnormal operation conditions. By reducing the ion beam setup time, it is feasible to shutoff the ion source generation and deflection subsystem during a wafer exchange period. The shutoff operation enables the cost reductions by reducing wastes of materials; manpower and other system resources while increase the overall system productivities.

### BACKGROUND OF THE INVENTION

1. Field of the Invention

This invention relates generally to methods and apparatus for carrying out ion implantation with ion beams using an ion implantation system. Specifically, this invention relates to improved methods and new implantation system configuration to accurately set up ion beam that requires reduced setup time with accuracy and repeatability to carry out ion implantation. With reduced setup time, this invention increases productivity.

2. Background

There are a number of problems faced by the industry in ion beam setups. The methods employed are slow and inefficient, and at times resulting in erroneous implants using the incorrect species. The searching and tuning algorithms are usually ineffectively exhaustive, erroneously incomplete, and sometimes fatally inaccurate, or just fail completely. The errors are not detected at the earliest possible time, but are propagated through the process only to be reported in the customers' final products, resulting in great lost of revenues. With fast and reliable ion beam setups in conjunction with judicious error checking and corrections, productivity in manufacturing using the described ion implantation system can be greatly enhanced.

Therefore, a need still exists in the art of ion implantation to provide improved method for setting up ion beams to resolve the problems and difficulties as now encountered by those of ordinary skill in the art and to improve manufacturing productivity in wafer implantations.

### SUMMARY OF THE PRESENT INVENTION

It is an object of the present invention to provide a well-tested method that is implemented in computer-optimized procedure that is accurate, repeatable, and fast whereby the difficulties and limitations as that encountered in the prior art technologies are overcome.

Specifically, it is the object of the present invention to be able to prepare the ion implantation system for requirements specified by users and customers accurately, reliably, consistently, repeatedly, and in the shortest time possible.

Briefly, in a preferred embodiment, the present invention discloses an ion implantation method. The ion implantation method includes:

(1) Early built-in checks in critical areas that ensure accuracy and enable corrective actions sooner if something should go wrong. Judicious checks are executed before data are obtained to ensure integrity and accuracy of the feedback that drives the setup process along the correct path. With these built-in checks, the system achieves repeatability of the final result.

(2) The formula-based searching algorithm for AMU that is accurate, fast, and repeatable using a feedback other than the beam current. The same formula is used to check for subsystems consistency and reliability to ensure accuracy of the ion beam being set up.

(3) The peaking algorithm is intelligent enough to avoid the common pitfalls of misinterpretation of data and achieve an accurate, reliable, and fast tuning with the help of “Trusty Recipes” as initial conditions and “Limits Parameters” as constraints.

(4) The use of a Graphical User's Interface (GUI) to minimize or even eliminate typographical errors, to enhance and facilitate interactions between system and human, and to monitor and react to abnormal and serious conditions.

(5) The ability to shutoff ion source generation and deflection subsystems during wafer exchange when the ion beam setup time is shorter than the said exchange. This enables the cost reduction in terms of materials, resources, and manpower and hence enhances productivity.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a diagram showing the major functional blocks of an implantation system of this invention;

FIG. 2 is a schematic diagram of the ion implantation system of this invention;

FIG. 3 is an example of the Beam Recipe, Table of Last Best Values (LBV), and Table of Limits.

FIG. 4 is a diagram for showing an algorithm for determining the peak of an ion beam.

FIG. 5 is a diagram depicting the auto beam setup procedure.

FIG. 6 is an approximated timing diagram of the implant process.

### DETAILED DESCRIPTION OF THE PREFERRED EMBODIMENT

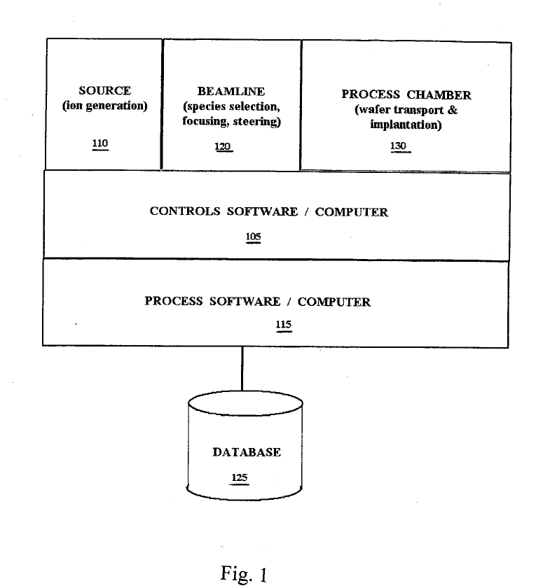

FIG. 1 is a functional block diagram for showing the ion implantation system of this invention. The ion implantation system of this invention as shown includes six major functional blocks. The source 110 generates ions and the ions are extracted from the source chamber as an ion beam. The ion beam is then guided by the beam line 120 to carry out species selection, beam steering and focus function. The focused ions are implanted on the wafers in the process chamber 130. The process chamber 130 further includes mechanisms to transport wafers and beam measuring devices to measure the ion beam projected into the process chamber 130.

FIG. 1 also includes the Controls Computer and Controls Software 105 that perform the primitive commands and high-level sequences (programs) that control all functionality of the ion implantation system. The Process Computer and Process Software 115 perform the top-level processes and jobs of wafer implantation. The Process Software executes the implant functions via the Controls Software. The database 125 contains information relevant to jobs and controls, including the “Trusty Recipes” and “Limits Parameters”, and is accessible via the Process Software.

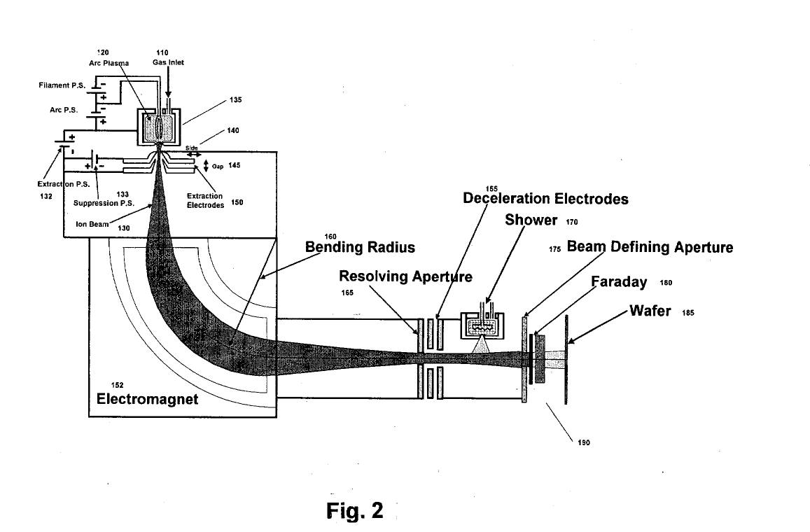

The method described below has been developed and tested successfully on an ion implantation system as that shown in FIG. 2. Several innovative procedures and tools have been implemented to achieve ion beam setups in about two minutes with repeatable and accurate results, comparing to the industry's average of about 5-15 minutes. Initially an ion beam 130 is generated from the ion source chamber 135 with a minimum of arc current by adjusting the side 140 and gap 145 of the extraction electrodes 150. The ion-selecting (AMU—Atomic Mass Unit) electromagnet 152 is tuned to separate the specific species. As in mass spectroscopy, an ion of a given mass and charge state that is accelerated to a final velocity by the extraction voltage, will travel in a circular path whose radius 160 is determined by the strength of a uniform, perpendicular magnetic field. Ions of different masses and charge states can be separated by using a strong electromagnet whose magnetic field can be controlled by the amount of current that flows through it. A procedure is made to ensure that the beam is generated from a correct ion source as the procedure of this invention specifically applied to determine that ion source indeed is the designated implanting species. It is accomplished by first applying an arc current to the ion source chamber 135 to strike an arc with arc plasma 120 and gas 110 containing the species. An ion beam is then generated by adjusting the extraction electrodes 150. Measurements of the beam current to determine specified ion characteristics such as mass and charge state and ion energy as that determined by the extraction voltage is made to ensure that it is within a known acceptable range. The measurements are performed by a combination of the Faraday current sensor 180 and magnetic field probe disposed inside the electromagnet 152. The magnetic field probe is used in the initial setting of the electromagnet current to obtain the required ion beam, and for consistency checking. The Faraday current sensor is used to determine the delivered beam current, and for peak tuning procedures.

During this period the ion source and other beam generating and controlling subsystems are being warmed up for operational stability. Then the arc current is increased accordingly with further operational procedures to check and control the stability of the ion beam. A peaking algorithm as will be further described below is introduced to center the beam's maximum to the target area, e.g., the target chamber 190, by tuning the AMU electromagnet unit 152. During the peak tuning process, techniques, such as adjusting the extraction electrodes 150 and deceleration electrodes 155, are also used to stabilize the beam such that erroneous beam data due to electrical discharges and other causes are eliminated. The optimal positions of these electrodes balance the maximum amount of current extracted due to the voltage difference supplied by the Extraction Power Supply 132 by placing them closer to the source 135 and avoid electrical discharges by positioning them not too close. If the electrodes are too close, electrical discharges (or commonly known as “shorts”) will occur and diminish the useful extracted current. The suppression voltage supplied by the Suppression Power Supply 133 also aids in beam generation and control. With this, the specified ion beam with precisely controlled functional characteristics is generated and steered to pass through the resolving aperture 165, and deceleration electrodes 155, processed by the electron shower 170, transmitted through the beam defining aperture 175 to reach the target area that contains the Faraday 180 for beam current measurement, and finally delivered to the wafer 185.

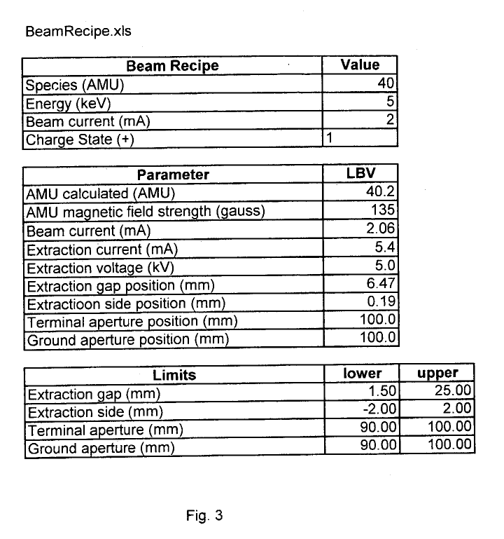

After a beam has been setup successfully for the very first time, a critical set of parameters, i.e., Last Best Values (LBV), is saved with the list of species, beam energy, beam current, and ion charge state in an entity called the Beam Recipe. An example of the Beam Recipe and LBV is shown in FIG. 3. The Beam Recipe is used to provide initial parameters to setup a similar specified ion beam in the future. The repeatability of setups has been achieved by the utilization of the Last Best Values. Beam Recipes that have been tested and verified, and used successfully to setup specified ion beams repeatedly are called “Trusty Recipes”.

The method also uses Limits Parameters that are a subset of the critical parameters of the Beam Recipe. The Limits Parameters defined the ranges of travel and step sizes for motors that control beam steerage, focusing, and optimization, and power supply limits for voltages and currents, and settling times for mechanical and electrical components. The utilization of the Limits Parameters has decreased the setup time to a large degree.

In order to achieve a greater, if not complete, coverage of setups for ion beams of varied species, beam energies, beam currents, and ion charge states, the Beam Recipe that contains the Last Best Values and Limits Parameters are stored in a database with an identifiable name. The Last Best Values can be updated after a successful setup. The Limits Parameters can be edited in an intuitive and easy to use GUI (Graphical User Interface). The separation of code and parameters have stabilized code development, and extended the capability of the system to be able to setup difficult ion beams with different parameters without having to modify the code. For those who possess ordinary skill in the art and for those who attempt to develop computer program that could be used to setup ion beams of great variation in requirements usually fail because by optimizing the program to satisfy a given set of requirements will either unable to optimize other requirements, or fail outright. For example, to tune a skinny beam will require a smaller step of change, but would take an inordinate amount of time for a fat beam. However, using a bigger step of change to tune a fat beam may fail to fine the skinny beam because it lies in between the steps and cannot be detected. By using the current new procedure, the Limits can be tailored to any required beam setup. As shown in FIG. 1 above, the block diagram illustrates the configuration of an implantation system with a controller and the interactions between a beam-setup and control program of this invention, a database of this invention for storing the operational parameters including the last best values and the Trusty Recipes, and the actual operation of the implantation system in setting up and the control of the beam.

A description of the procedure is described below to provide a general understanding as to how the improved method of beam setup can improve accuracy of beam setup, repeatability of the setup processes and time saving in setting up the ion beam.

Procedures that Ensure Accuracy

(1) Use of “Species-Energy Search and Check”—This procedure uses the magnetic field measured by the Hall Probe, ion charge state, and extraction voltage to calculate the current required for the AMU electromagnet to deflect the selected ion beam close to the target. The same equation is used to perform a “sanity” check on the system power supplies, and Hall Probe. The formula used is given below:

AMUcalculated=k*(Bprobe**2* Charge)/Vext

Where AMUcalculated is the AMU (Atomic Mass Unit, such as 11 for Boron),

k is a system-dependent constant,

Bprobe is the magnetic field readback from the probe,

Charge is the ion charge state (such as singly, doubly, or triply charge)

Vext is the extraction voltage.

The magnetic field probe (Bprobe) is a Hall-effect magnetic field measuring device that is located inside the electromagnet 152. The Extraction voltage is supplied by the Extraction Power Supply 132 that creates a voltage drop to accelerate the ions out of the source 135.

(2) Use of Peaking algorithm—This algorithm is used in peaking (or tuning) the ion beam by adjusting components with feedback from the beam current reading. The components include AMU electromagnet 152 and mechanical electrodes 140, 145, 155. The peaking algorithm is stated below.

(3) Use of Last Best Values as starting values for critical parameters.

(4) Generate and verify a minimum and sufficient set of Trusty Recipes to cover most, if not all, beam setups as specified by the ion implantation system. If a particular setup should fail, the system will search for and setup a nearby Trusty Recipe as a refuge of stability, and continue to proceed and setup for the required and target beam. The set of Trusty Recipes is dictated by manufacturing requirements of the “tool” (the ion implantation system) that is determined by the customers. Some customers only use a particular tool for one or two species, maybe in a limited range. Others may use it to do most of the implantation processes. For these, a larger set of Trusty Recipes is required to cover these cases. Unlike our competition, a minimum set is suffice because our tool has a wide range of tolerance in terms of beam current and energy, and using a close enough ” Trusty Recipe” one can achieve the required beam setting.

(5) Use of “Touch Tune” to assist initial or manual (“teaching”) setup to achieve the required beam current quickly. “Touch Tune” is the procedure that can start at a given state and continue the tuning procedure to achieve the required target beam. Touch Tune is a small subset of Beam Tune. Beam Tune is used to set up species that is different from the previous setup. It could possibly involve a change of gas 110, stabilizing the source 135, and use of the LBV in the Trusty Recipe to initialize the AMU magnet and electrodes, and tune the beam as described earlier. Whereas Touch Tune assumes all the initialization and stabilization has been completed, but the beam is not quite optimized yet. It can be perceived as the final beam tune and optimization process. It usually runs in a fraction of time required by the already fast Beam Tune.

(6) Use of “Touch Tune” in the rare occasion of automated beam setup failure and a skilled operator is required for assistance. The “Pause” and “Resume” functions are provided. The operator can select “Pause”, and assist setup by changing some of the parameters or experimenting new values of parameters. Once the hurdle has been overcome, he/she can select the “Resume” function to use “Touch Tune” to continue tuning toward the target required beam.

(7) Use of a Table of beam current versus extraction current for different species as another “sanity-check” for the system.

Procedures that Ensure Repeatability

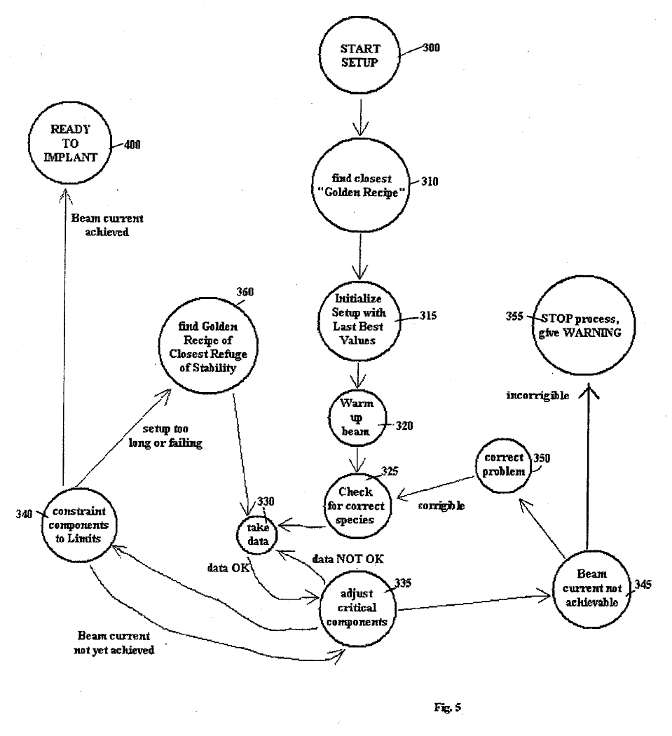

The following procedures are used in determining if the beam data taken by the Faraday sensor 180 is good or not. This step is depicted in FIG. 5 near the bottom of the diagram labeled as “take data”, and “data NOT OK”. With these procedures, only good data are used and thus avoiding misinterpretation of data and incorrect decisions made in the beam setup procedure.

(1) “CleanBeam”—This procedure suspends the setup procedure when an electrical discharge from the extraction power supply has been detected, and waits for a specified amount of time before continuing the setup procedure.

(2) “CleanArc”—This procedure suspends the setup procedure when arc instability has been detected, and wait for a specified amount of time before continuing.

(3) “CleanDecelSuppression”—This procedure suspends the setup procedure when an electrical discharge from the decel suppression power supply has been detected, and waits for a specified amount of time before continuing.

(4) “CleanPressure”—This procedure suspends the setup procedure when the pressure in the process chamber is above 5*10**(−5) Torr, and waits for the pressure to come down before continuing.

(5) “Suppr_OK”—This procedure tests for reasonable extraction suppression current, and execute corrections when the current is too high.

Procedures that Reduce Setup Time

(1) AMU tune and Electrode tune using the peaking algorithm.

With the initial values provided by the Trusty Recipe, all critical subsystems, such as AMU magnet current, and electrode positions, are set in the correct environment to achieve the required beam. No time is wasted in adjusting the subsystems one at a time to configure them to this known state.

(2) AMU tune and Electrode tune using Limits Parameters With the Limits, the subsystems are constraint to certain ranges in their adjustments and can proceed quickly to achieve the required beam setup. This will avoid the “snow-balling effect” of one bad adjustment leading to others, and ending up in irrecoverable situations, or at best wasting time.

Peak Tuning Algorithm

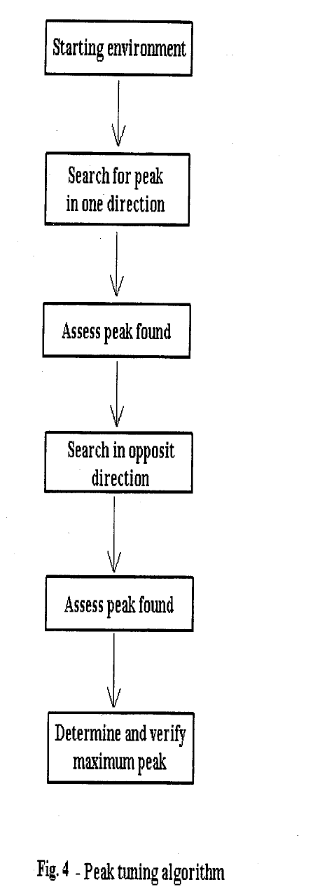

Referring to FIG. 4 for descriptions below of the peaking algorithm for carrying out the peak-tuning procedures.

NOTE: Starting environment utilizes information in the “Trusty Recipes”. Peak assessment utilizes those in the “Limits Parameters”.

This procedure is not only accurate, reliable, and fast for single-peak search and tune, it is just as accurate, reliable, and fast for twin-peak search and tune.

FIG. 5 is a diagram for showing the processing steps of ion beam setup to apply the improved method for ion beam setup as generally described above. The process begins with a step to “Start Setup” (step 300) by first finding the closest Trusty Recipe available (step 310) to begin the beam setup process by using a set of latest optimal system tuning parameters. The initial setup process is carried out using the latest best values (step 315), an example of the Trusty Recipe is shown as a Beam-recipe table as FIG. 3 above. In the meantime, a process is carried out to warm up the beam (step 320). A species correctness check is performed to determine if an ion source of correct species is used (step 325) to make sure the implantation is not processed with incorrect ion species. Data are taken (step 330) to compare and adjust the critical components (step 335) continuously to achieve the desired target beam current. During these steps, data are filtered and only reasonable data are used. While adjusting, the Limits Parameters are used to constraint the adjustment of the critical components (step 340). If the desired beam current has been achieved within the constraints, the setup is done and it is ready for implant (step 400). If the beam current is not achievable (step 345) the system will attempt to correct the problem (step 350). If it is not correctable, it will send a warning and prompt for user intervention and assistance (step 355). If the setup is taking too long, the system will search for the next closest Trusty Recipe (step 360) and repeat the process by taking data and adjusting the critical components (steps 330, and 335).

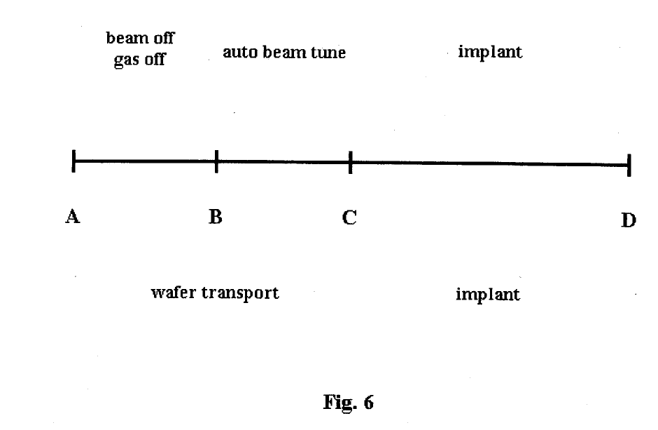

Using the above procedures accurate and repeatable ion beam setups can be completed in reduced time, e.g., in two to five minutes. The setup time is therefore considerably less in comparison to the time required by the wafer handling system to carry out a wafer exchange process even for a wafer handling system that can handle 260 wafers per hour or more. During the time when the system is performing wafer exchange, i.e., loading and unloading the wafers, the source and beam line subsystems can be shutoff. This feature will prolong the filament lifetime, decrease the gas utilization, and reduce the power consumption of the various power supplies, such as for the AMU magnet. With longer filament lifetime and longer period between gas bottle changes, the system downtime for maintenance is also reduced and valuable resources of manpower, and materials are conserved. Since the setup time is reduced and ion beam of high quality can be setup repeatedly, the process of shutting down the source and the beam line subsystems would not impact the throughput of the system. Cost savings and improvement of system performance and productivity are achieved with increased uptime and reduced material and energy costs. Since the setup specification can vary greatly, so is the ion beam setup time. However, an estimation can be made as depicted in FIG. 6. The horizontal line represents time. From A to D is the total time for an implant job. From A to C is the approximated wafer transport portion of the total time. From C to D is the implant portion of the total time. Similarly, while the wafers are transported, the beam, gas, and some power supplies are shutoff from A to B to conserve resources and power. From B to C is the approximated portion for ion beam setup process as described above. From C to D is the implant portion where gas and beam are continuously turned on. The cost saving portion (A to B) can be a substantial part during wafer transport (A to C). The actual cost saving depends on the beam current and energy as specified by the customers.

According to above descriptions, this invention discloses a method for setting up an ion beam in an ion implantation apparatus. The method includes a step of performing a setup initialization by checking and using a set of last best values of operational parameters identified as a Trusty recipe. In a preferred embodiment, the method further includes a step of performing a check to assure a correct ion species is used in a starting stage of setting up the ion beam. In another preferred embodiment, the method further includes performing a beam warm-up operation in parallel to the step of performing the check to assure a correct ion species is used. In another preferred embodiment, the method further includes performing an operation to generate a set of best last values for use as a Trusty recipe for setting up the ion beam. In another preferred embodiment, the step of performing a setup initialization by checking and using a set of last best values of operational parameters identified as a Trusty recipe further comprising a step of storing the set of last best values of operational parameters in a database. In another preferred embodiment, the step of performing the operation to generate a set of best last values for use as a Trusty recipe for setting up the ion beam further comprising a step of storing the set of last best values as a Trusty recipe in a database. In another preferred embodiment, the method further includes a step of performing a beam diagnosis if a determination is made of a use of an incorrect ion species in the starting stage of setting up the ion beam.

In essence this invention discloses an ion implantation system that includes a means for controlling an operation for setting up an ion beam by retrieving a set of Last Best Values (LBV) parameters from a database. In a different preferred embodiment, this invention further discloses an ion implantation system that includes a means for controlling an operation of an ion beam wherein the means for controlling further includes a separate database for storing parameters available for executing a program on the means for controlling the operation. In another preferred embodiment, the means for controlling further including a means for performing a setup initialization by checking and using a set of last best values of operational parameters identified as a trusty recipe stored in the database. In another preferred embodiment, the means for controlling further includes a means for checking and assuring a correct ion species is used in a starting stage of setting up the ion beam.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

We claim:

1. A method for setting up an ion beam in an ion implantation apparatus comprising:
performing a check to assure a correct ion species is used in a starting stage of setting up said ion beam.

2. The method for of claim 1 further comprising:
performing a beam warm-up operation in parallel to said step of performing said check to assure a correct ion species is used.

3. A method for setting up an ion beam in an ion implantation apparatus comprising:
performing a setup initialization by checking and using a set of last best values of operational parameters identified as a Trusty recipe.

4. The method for of claim 3 further comprising:
performing a check to assure a correct ion species is used in a starting stage of setting up said ion beam.

5. The method for of claim 4 further comprising:
performing a beam warm-up operation in parallel to said step of performing said check to assure a correct ion species is used.

6. The method for of claim 3 further comprising:
performing an operation to generate a set of best last values for use as a Trusty recipe for setting up said ion beam.

7. The method for of claim 3 wherein:
said step of performing a setup initialization by checking and using a set of last best values of operational parameters identified as a Trusty recipe further comprising a step of storing said set of last best values of operational parameters in a database.

8. The method for of claim 6 wherein:
said step of performing said operation to generate a set of best last values for use as a Trusty recipe for setting up said ion beam further comprising a step of storing said set of last best values as a Trusty recipe in a database.

9. The method for of claim 4 further comprising:
performing a beam diagnosis if a determination is made of a use of an incorrect ion species in said starting stage of setting up said ion beam.

10. An ion implantation apparatus comprising:
a data processor having a database for controlling an ion implantation process including a means for performing a check to assure a correct ion species is used in a starting stage of setting up said ion beam.

11. The ion implantation apparatus of claim 10 wherein:
said data processor further having a program for performing a beam warm-up operation in parallel to said step of performing said check to assure a correct ion species is used.

12. An ion beam in an ion implantation apparatus comprising:
a data processor having a database for controlling an ion implantation process including a means performing a setup initialization by checking and using a set of last best values of operational parameters identified as a trusty recipe stored in said database.

13. The apparatus of claim 12 further comprising:
a means for checking and assuring a correct ion species is used in a starting stage of setting up said ion beam.

14. The apparatus of claim 13 wherein:
said data processor further controlling said ion implantation system to perform a beam warm-up operation in parallel to an operation for checking and assuring a correct ion species is used.

15. The apparatus of claim 12 wherein:
said database further comprising a set of best last values for use as a trusty recipe for setting up said ion beam.

16. The apparatus of claim 12 wherein:
said data processor for controlling said ion implantation process including a program for performing a setup initialization by checking and using a set of last best values of operational parameters identified as a trusty recipe stored in said database.

17. The method for of claim 4 further comprising:
said data processor for controlling said ion implantation process including a program for performing a beam diagnosis if a determination is made of a use of an incorrect ion species in said starting stage of setting up said ion beam.

18. An ion implantation system comprising:
a means for controlling an operation for setting up an ion beam by retrieving a set of Last Best Values (LBV) parameters from a database.

19. An ion implantation system comprising:
a means for controlling an operation of an ion beam wherein said means for controlling further includes a separate database for storing parameters available for executing a program on said means for controlling said operation.

20. The ion implantation system of claim 19 wherein:
said means for controlling further including a means for performing a setup initialization by checking and using a set of last best values of operational parameters identified as a trusty recipe stored in said database.

21. The ion implantation system claim 19 wherein:
Said means for controlling further includes a means for checking and assuring a correct ion species is used in a starting stage of setting up said ion beam.
